(19) United States
(12) Patent Application Publication
(10) Pub. No.: US 2026/0114265 A1
(43) Pub. Date: Apr. 23, 2026

(54) MULTILAYER WIRING CONNECTION STRUCTURE FOR REDUCING CONTACT RESISTANCE, AND MANUFACTURING METHOD THEREFOR

(71) Applicant: IUCF-HYU (INDUSTRY-UNIVERSITY COOPERATION FOUNDATION HANYANG UNIVERSITY), Seoul (KR)

(72) Inventor: Jin Pyo HONG, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 18/860,475

(22) PCT Filed: Apr. 28, 2023
(86) PCT No.: PCT/KR2023/005866

§ 371 Date: Jul. 2, 2025

(30) Foreign Application Priority Data
Apr. 28, 2022 (KR) 10-2022-0052909

(51) Int. Cl. H10W 20/41; H10P 50/00; H10P 50/26; H10P 50/66; H10W 20/00

(52) U.S. Cl. CPC H10W 20/438; H10P 50/267; H10P 50/66; H10P 50/71; H10W 20/0595; H10W 20/425; H10W 20/435

(57) ABSTRACT

A multilayer wiring connection structure and a method for manufacturing the same are provided. The multilayer wiring connection structure includes a first insulating film positioned on a substrate, a first wiring positioned within the first insulating film, a second insulating film positioned on the first wiring, and a second wiring positioned within the second insulating film and in contact with the first wiring. The first wiring comprises a trench having at least one anisotropically etched portion and at least one isotropically etched portion under the second wiring, and the second wiring comprises an extension filling the trench.

### TECHNICAL FIELD

The present invention relates to a semiconductor device, and more particularly, to a semiconductor device including a multilayer wiring connection structure.

### BACKGROUND ART

Recently, semiconductor devices are developing toward high integration, and the design rules of semiconductor devices are decreasing. Accordingly, multilayer metal wiring structure is applied, and this multilayer wiring connection structure includes a via made of a conductive metal material penetrating the interlayer insulating film formed on semiconductor elements to electrically connect a plurality of wirings formed on the upper and lower portions of the interlayer insulating film.

In order to implement high performance through low-power operation in these semiconductor devices, and as device scaling is accelerated, research is being conducted to reduce the delay time of semiconductor devices by lowering the contact resistance between multilayer wirings. To this end, research is being conducted on using new materials with low resistivity as wiring or contact filling materials, and also on processes that do not use barrier metals. However, even if such new materials are used, it may be difficult to resolve the increase in resistance due to the decrease in contact area caused by device miniaturization.

### DETAILED DISCLOSURE OF THE INVENTION

### Technical Problem

The problem to be solved by the present invention is to provide a method for reducing contact resistance by increasing the contact area in a multilayer wiring connection.

The technical problems of the present invention are not limited to the technical problems mentioned above, and other technical problems not mentioned will be clearly understood by those skilled in the art from the description below.

### Technical Solution

In order to solve the above technical problem, one aspect of the present invention provides a multilayer wiring connection structure. The multilayer wiring connection structure includes a first insulating film positioned on a substrate, a first wiring positioned within the first insulating film, a second insulating film positioned on the first wiring, and a second wiring positioned within the second insulating film and in contact with the first wiring. The first wiring comprises a trench having at least one anisotropically etched portion and at least one isotropically etched portion under the second wiring, and the second wiring comprises an extension filling the trench.

The trench may have the isotropically etched portion at the top, and may have the anisotropically etched portion under the isotropically etched portion. The trench may include a plurality of at least one of the anisotropically etched portion and the isotropically etched portion, and the anisotropically etched portion and the isotropically etched portion may be alternately arranged. The trench may include 1 to 4 of the anisotropically etched portions and 1 to 4 of the isotropically etched portions.

In order to solve the above technical problem, one aspect of the present invention provides a method for manufacturing a multilayer wiring connection structure. First, a first insulating film and a first wiring positioned within the first insulating film are formed on a substrate. The first wiring is etched to form a trench having at least one anisotropically etched portion and at least one isotropically etched portion within the first wiring. A second wiring is formed on the first wiring, wherein the second wiring has an extension portion filling the trench.

The trench may be formed by forming a photoresist pattern exposing a portion of the first wiring on the first wiring, and then etching the first wiring using the photoresist pattern as a mask. When etching the first wiring, isotropic etching may be performed to form the isotropically etched portion, and then the bottom surface of the isotropically etched portion may be anisotropically etched to form the anisotropically etched portion. When etching the first wiring, isotropic etching and anisotropic etching may be alternately performed to alternately form the anisotropically etched portion and the isotropically etched portion.

### Advantageous Effects

As described above, according to one embodiment of the present invention, since the second wiring has an extension that fills the trench in the first wiring, the contact area between the first wiring and the second wiring can be increased. In this way, the first wiring and the second wiring can be in contact not only in a two-dimensional plane but also in the thickness direction of the first wiring, so that the contact area is increased, and thus the contact resistance can be reduced. Such a decrease in the contact resistance between the wirings can lead to an increase in the operating speed of the device.

However, the effects of the present invention are not limited to the effects mentioned above, and other effects not mentioned will be clearly understood by those skilled in the art from the description below.

### BRIEF DESCRIPTION OF DRAWINGS

FIGS. 1, 2, and 3 are schematic diagrams showing a method for manufacturing a multilayer wiring connection structure according to one embodiment of the present invention.

FIGS. 4 to 10 are schematic diagrams showing multilayer wiring connection structures according to other embodiments of the present invention, respectively.

### MODES OF THE INVENTION

Hereinafter, in order to explain the present invention in more detail, preferred embodiments according to the present invention will be described in more detail with reference to the attached drawings. However, the present invention is not limited to the embodiments described herein and may be embodied in other forms. In the drawings, where a layer is referred to as being “on” another layer or substrate, it may be formed directly on the other layer or substrate, or there may be a third layer interposed between them. In these embodiments, the terms “first,” “second,” or “third” are not intended to impose any limitations on the components, but should be understood as terms only used to distinguish the components.

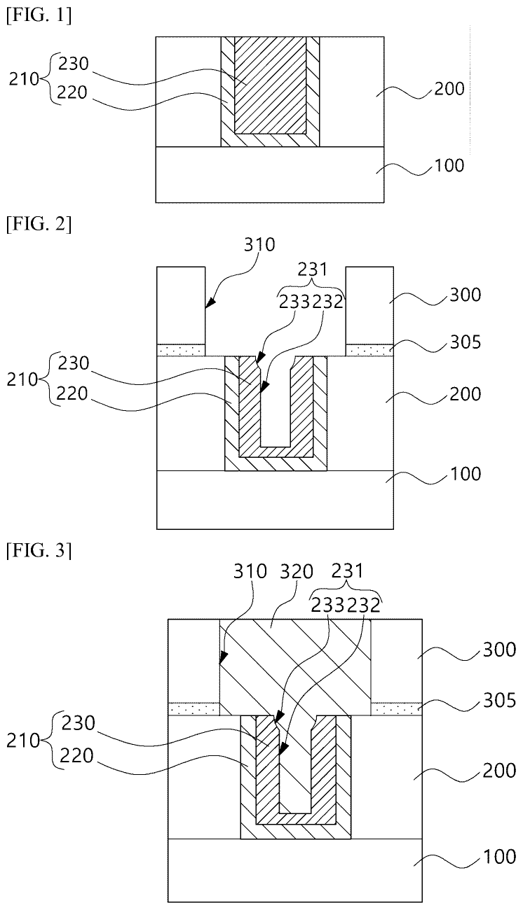

FIG. 1, FIG. 2, and FIG. 3 are schematic diagrams showing a method for manufacturing a multilayer wiring connection structure according to one embodiment of the present invention. The multilayer wiring connection structure can be manufactured through a BEOL (Back End Of Line) process of a semiconductor process.

Referring to FIG. 1, semiconductor elements (not shown) such as transistors can be formed on a substrate 100. A first insulating film 200 covering the semiconductor elements and a first wiring 210 located within the first insulating film 200 can be formed on the substrate 100.

The first insulating film 200 may be a silicon oxide film, a silicon nitride film, or a low-k insulating film. The low-k insulating film may be a film having a lower permittivity than that of the silicon oxide film, and may be, for example, a film having a permittivity of 3 or less. The low-k insulating film may be an organic polymer film such as polyimide, poly(arylene ether) (PAE), a cyclobutene derivative, an aromatic thermosetting polymer (trade name: SiLK), or an organic silicate film having nanopores introduced, for example, HSQ (hydrogen silsesquioxane) and MSQ (methyl silsesquioxane).

The first wiring 210 may be a metal wiring and may include a first metal filling portion 230 and a barrier film 220 between the first metal filling portion 230 and the first insulating film 200. The barrier film 220 may be a film that prevents the metal of the first metal filling portion 230 from diffusing into the surrounding insulating film and may be titanium (Ti), titanium nitride (TiN), or a multilayer thereof. However, it is not limited thereto, and the barrier film 220 may be omitted. The first metal filling portion 230 may be aluminum, an aluminum-copper alloy (AlCu), copper, or a multilayer thereof. The first wiring 210 may be formed by a damascene process, but is not limited thereto.

In addition, the first wiring 210 may be a contact plug, a via, or a signal line, but is not limited thereto.

Referring to FIG. 2, after sequentially forming an etch stop layer 305 and a second insulating film 300 on the first insulating film 200, a contact hole 310 exposing at least a portion of the upper surface of the first wiring 210 can be formed within the second insulating film 300 and the etch stop layer 305. When the contact hole 310 has a wider width than the first wiring 210, the etch stop layer 305 can suppress or prevent the first insulating film 200 under the contact hole 310 from being etched by etching the second insulating film 300 and then etching the etch stop layer 305 in the process of forming the contact hole 310.

After forming a photoresist pattern (not shown) that exposes a portion of the upper part of the first wiring 210 within the contact hole 310 on the substrate, the first wiring 210 may be etched using the photoresist pattern as a mask to form a trench 231 within the first wiring 210 and the trench 231 may be extended from the contact hole 310. However, the present invention is not limited thereto, and in the case where the contact hole 310 has a narrower width than the first wiring 210, the second insulating film 300 around the contact hole 310 may be used as a mask to form the trench 231 without forming the photoresist pattern separately and the trench 231 may be extended from the contact hole 310.

The trench 231 may include at least one anisotropically etched portion 232 and at least one isotropically etched portion 233. In addition, the anisotropically etched portion 232 and the isotropically etched portion 233 may be alternately arranged within the trench 231. The anisotropically etched portion 232 may be a region formed by anisotropic etching, and may have a sidewall in the form of a straight line when viewed in cross-section, specifically, a shape perpendicular to the substrate 100. Meanwhile, the isotropically etched portion 233 may be a region formed by isotropic etching, and may have a sidewall in the form of a curve when viewed in cross-section. The anisotropically etching may be performed by dry etching such as reactive ion etching (RIE), and the isotropic etching may be performed by wet etching, but is not limited thereto.

Referring again to FIG. 2, the trench 231 may have an anisotropically etched portion 232 below the isotropically etched portion 233. To this end, when etching the first wiring 210 to form the trench 231, isotropic etching may be performed to form the isotropically etched portion 233, and then anisotropic etching may be performed to form the anisotropically etched portion 232.

Referring to FIG. 3, a second wiring 320 may be formed to fill the contact hole 310 and the trench 231. The second wiring 320 may be made of aluminum, an aluminum-copper alloy (AlCu), copper, or a multilayer thereof. Thereafter, the second wiring 320 can be chemical mechanical polished to flatten its surface so that it has almost the same level as the second insulating film 300.

However, it is not limited thereto, and before forming the second insulating film 300, the trench 231 can be formed, and a metal layer having a predetermined thickness and filling the trench 231 can be formed on the first insulating film 200, and then the metal layer may be patterned to form the second wiring 320, and then the second insulating film 300 may be formed on the second wiring 320, and the second insulating film 300 may be chemical mechanical polished to flatten the surface of the second insulating film 300 to have almost the same level as the second wiring 320.

The first wiring 210 and the second wiring 320 can be formed using one of physical vapor deposition, chemical vapor deposition, or atomic layer deposition methods, regardless of each other.

As described above, since the second wiring 320 has an extension that fills the trench 231 in the first wiring 210, the contact area between the first wiring 210 and the second wiring 320 can be increased. In this way, the first wiring 210 and the second wiring 320 can be in contact not only in a two-dimensional plane but also in the thickness direction of the first wiring 210, so the contact area is increased, and thus the contact resistance can be reduced. Such a decrease in the contact resistance between the wirings can lead to an increase in the operating speed of the device.

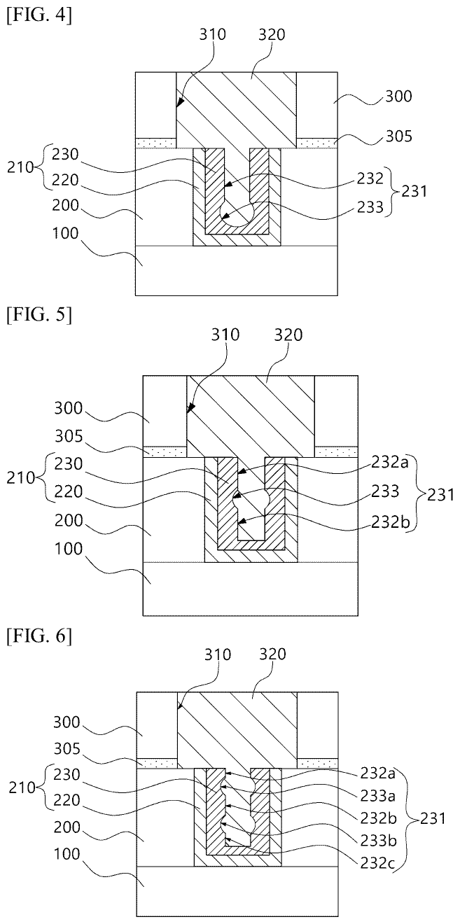

FIGS. 4 to 10 are schematic diagrams each showing multilayer wiring connection structure according to other embodiments of the present invention. The multilayer wiring connection structure according to each embodiment is similar to the multilayer wiring connection structure or the manufacturing method thereof described with reference to FIGS. 1 to 3, except for what is described below.

Referring to FIG. 4, a trench 231 extending from a contact hole 310 into a first wiring 210 may have an isotropically etched portion 233 below an anisotropically etched portion 232. To this end, when etching the first wiring 210 to form the trench 231, anisotropic etching may be performed to form the anisotropically etched portion 232, and then isotropic etching may be performed on the bottom surface of the anisotropically etched portion 232 to form the isotropically etched portion 233.

Referring to FIG. 5, a trench 231 extending from a contact hole 310 into a first wiring 210 may have an isotropically etched portion 233 below a first anisotropically etched portion 232a, and a second anisotropically etched portion 232b below the isotropically etching portion 233. To this end, when etching the first wiring 210 to form the trench 231, the first anisotropic etching may be performed to form the first anisotropically etched portion 232a, then isotropic etching may be performed on the bottom surface of the first anisotropically etched portion 232a to form the isotropically etched portion 233, and then the second anisotropic etching may be performed on the bottom surface of the isotropically etched portion 233 to form the second anisotropically etched portion 232b.

Referring to FIG. 6, a trench 231 extending from a contact hole 310 into a first wiring 210 may have a first anisotropically etched portion 232a, a first isotropically etched portion 233a, a second anisotropically etched portion 232b, a second isotropically etched portion 233b, and a third anisotropically etched portion 232c arranged in sequence from top to bottom. To this end, when etching the first wiring 210 to form the trench 231, a first anisotropic etching may be performed to form a first anisotropically etched portion 232a, a first isotropic etching may be performed on the bottom surface of the first anisotropically etched portion 232a to form a first isotropically etched portion 233a, a second anisotropic etching may be performed on the bottom surface of the first isotropically etched portion 233a to form a second anisotropically etched portion 232b, a second isotropic etching may be performed on the bottom surface of the second anisotropically etched portion 232b to form a second isotropically etched portion 233b, and a third anisotropic etching may be performed on the bottom surface of the second isotropically etched portion 233b to form a third anisotropically etched portion 232c.

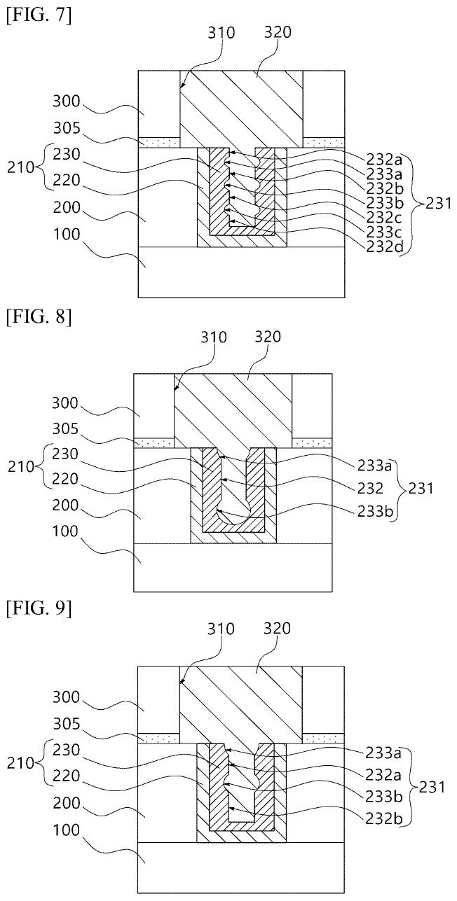

Referring to FIG. 7, a trench 231 extending from a contact hole 310 into a first wiring 210 may have a first anisotropically etched portion 232a, a first isotropically etched portion 233a, a second anisotropically etched portion 232b, a second isotropically etched portion 233b, a third anisotropically etched portion 232c, a third isotropically etched portion 233c, and a fourth anisotropically etched portion 232d arranged in sequence from top to bottom. To this end, when etching the first wiring 210 to form the trench 231, a first anisotropic etching may be performed to form a first anisotropically etched portion 232a, a first isotropic etching may be performed on the bottom surface of the first anisotropically etched portion 232a to form a first isotropically etched portion 233a, a second anisotropic etching may be performed on the bottom surface of the first isotropically etched portion 233a to form a second anisotropically etched portion 232b, a second isotropic etching may be performed on the bottom surface of the second anisotropically etched portion 232b to form a second isotropically etched portion 233b, a third anisotropic etching may be performed on the bottom surface of the second isotropically etched portion 233b to form a third anisotropically etched portion 232c, and a third isotropic etching may be performed on the bottom surface of the third anisotropically etched portion 232c to form a third isotropically etched portion 233c, and a fourth anisotropic etching may be performed on the bottom surface of the third isotropically etched portion 233c to form a fourth anisotropically etched portion 232d.

Referring to FIG. 8, a trench 231 extending from a contact hole 310 into a first wiring 210 may have a first isotropically etched portion 233a, an anisotropically etched portion 232, and a second isotropically etched portion 233b arranged sequentially from top to bottom. To this end, when etching the first wiring 210 to form the trench 231, the first isotropic etching may be performed to form the first isotropically etched portion 233a, an anisotropic etching may be performed on the bottom surface of the first isotropically etched portion 233a to form the anisotropically etched portion 232, and second isotropic etching may be performed on the bottom surface of the anisotropically etched portion 232 to form the second isotropically etched portion 233b.

Referring to FIG. 9, a trench 231 extending from a contact hole 310 into a first wiring 210 may have a first isotropically etched portion 233a, a first anisotropically etched portion 232a, a second isotropically etched portion 233b, and a second anisotropically etched portion 232b arranged in sequence from top to bottom. To this end, when etching the first wiring 210 to form the trench 231, a first isotropic etching may be performed to form a first isotropically etched portion 233a, a first anisotropic etching may be performed on the bottom surface of the first isotropically etched portion 233a to form a first anisotropically etched portion 232a, a second isotropic etching may be performed on the bottom surface of the first anisotropically etched portion 232a to form a second isotropically etched portion 233b, and then a second anisotropic etching may be performed on the bottom surface of the second isotropically etched portion 233b to form a second anisotropically etched portion 232b.

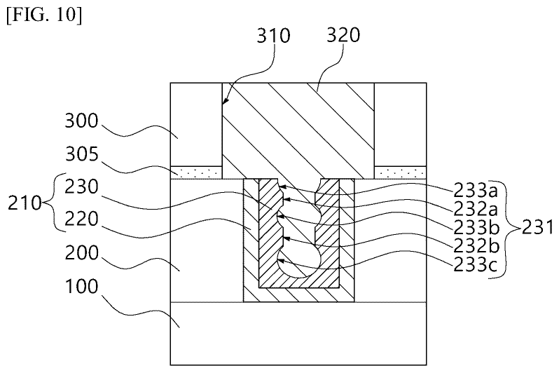

Referring to FIG. 10, a trench 231 extending from a contact hole 310 into a first wiring 210 may have a first isotropically etched portion 233a, a first anisotropically etched portion 232a, a second isotropically etched portion 233b, a second anisotropically etched portion 232b, and a third isotropically etched portion 233c arranged in sequence from top to bottom. To this end, when etching the first wiring 210 to form the trench 231, a first isotropic etching may be performed to form a first isotropically etched portion 233a, a first anisotropic etching may be performed on the bottom surface of the first isotropically etched portion 233a to form a first anisotropically etched portion 232a, a second isotropic etching may be performed on the bottom surface of the first anisotropically etched portion 232a to form a second isotropically etched portion 233b, a second anisotropic etching may be performed on the bottom surface of the second isotropically etched portion 233b to form a second anisotropically etched portion 232b, and then a third isotropic etching may be performed on the bottom surface of the second anisotropically etched portion 232b to form a third isotropically etched portion 233c.

As shown in FIGS. 3, 8, 9, and 10, when the uppermost part of the trench 231 has an isotropically etched portion 233 or 233a, the entrance to the trench 231 is wide, so that conformal deposition at the entrance can be induced when the second wiring 320 is deposited.

In addition, as shown in FIGS. 5 to 10, when the trench 231 includes both an isotropically etched portion and an anisotropically etched portion, and further includes at least one of another isotropically etched portion and another anisotropically etched portion, the contact area can be larger. Furthermore, as the number of alternately arranged isotropically and anisotropically etched portions increases, the contact area can become larger. As an example, the isotropically etched portions can be included 1 to 4 times, and the anisotropically etched portions can be included 1 to 4 times.

While the exemplary embodiments of the present invention have been described above, those of ordinary skill in the art should understood that various changes, substitutions and alterations may be made herein without departing from the spirit and scope of the present invention as defined by the following claims.

1. A multilayer wiring connection structure comprising:
a first insulating film positioned on a substrate and a first wiring positioned within the first insulating film; and
a second insulating film positioned on the first wiring, and a second wiring positioned within the second insulating film and in contact with the first wiring,
wherein the first wiring includes a trench having at least one anisotropically etched portion and at least one isotropically etched portion under the second wiring, and the second wiring includes an extension filling the trench.

2. The multilayer wiring connection structure of claim 1, wherein the trench has the isotropically etched portion at top, and has the anisotropically etched portion under the isotropically etched portion.

3. The multilayer wiring connection structure of claim 1, wherein the trench includes a plurality of at least one of the anisotropically etched portion and the isotropically etched portion, and the anisotropically etched portion and the isotropically etched portion are alternately arranged.

4. The multilayer wiring connection structure of claim 3, wherein the trench includes 1 to 4 of the anisotropically etched portion and 1 to 4 of the isotropically etched portion.

5. A method for manufacturing a multilayer wiring connection structure comprising:
forming a first insulating film and a first wiring positioned within the first insulating film on a substrate;
etching the first wiring to form a trench having at least one anisotropically etched portion and at least one isotropically etched portion within the first wiring; and
forming a second wiring on the first wiring,
wherein the second wiring has an extension filling the trench.

6. The method of claim 5, wherein the trench is formed by forming a photoresist pattern exposing a portion of the first wiring on the first wiring, and then etching the first wiring using the photoresist pattern as a mask.

7. The method of claim 5, wherein, when etching the first wiring, isotropic etching is performed to form the isotropically etched portion, and then a bottom surface of the isotropically etched portion is anisotropically etched to form the anisotropically etched portion.

8. The method of claim 5, wherein when etching the first wiring, isotropic etching and anisotropic etching are alternately performed to alternately form the anisotropically etched portion and the isotropically etched portion.
